(19) United States
(12) Patent Application Publication
(10) Pub. No.: US 2026/0011620 A1
(43) Pub. Date: Jan. 8, 2026

(54) SEMICONDUCTOR DEVICES

(71) Applicant: Samsung Electronics Co., Ltd., Suwon-si (KR)

(72) Inventors: Keun Hwi CHO, Suwon-si (KR); Kyoungwoo LEE, Suwon-si (KR); Hagju CHO, Suwon-si (KR)

(73) Assignee: Samsung Electronics Co., Ltd., Suwon-si (KR)

(21) Appl. No.: 18/968,653

(22) Filed: Dec. 4, 2024

(30) Foreign Application Priority Data
Jul. 2, 2024 (KR) 10-2024-0086799

(51) Int. Cl. H01L 23/373; H01L 23/00; H01L 23/48; H01L 23/528

(52) U.S. Cl. CPC H01L 23/3731; H01L 23/481; H01L 23/5286; H01L 24/13; H10D 30/502; H10D 30/6211; H01L 2224/13026

(57) ABSTRACT

A semiconductor device includes a transistor layer including a semiconductor substrate and gate structures on an upper surface of the semiconductor substrate, an upper substrate on the transistor layer, an upper wiring layer disposed between the transistor layer and the upper substrate and including upper conductive lines, a bonding layer between the upper wiring layer and the upper substrate, and a lower wiring layer disposed on a lower surface of the semiconductor substrate and including lower conductive lines. The transistor layer is disposed between the lower wiring layer and the upper wiring layer. The bonding layer includes a material having higher thermal conductivity than silicon oxide, and a dopant concentration of the upper substrate is lower than a dopant concentration of the semiconductor substrate.

### CROSS-REFERENCE TO RELATED APPLICATION

This application claims priority from Korean Patent Application No. 10-2024-0086799, filed on Jul. 2, 2024 in the Korean Intellectual Property Office, and all the benefits accruing therefrom under 35 U.S.C. 119, the entire contents of which are hereby incorporated by reference.

### FIELD

Apparatuses and methods consistent with the present disclosure relate generally to semiconductor devices, more specifically, a semiconductor device including a field-effect transistor and a method for manufacturing the same.

### BACKGROUND

Semiconductor devices may include an integrated circuit configured with metal oxide semiconductor field-effect transistors (MOSFETs). As the size and design rule of semiconductor devices are reduced, scaling down of MOSFETs are accelerated. The scaling down of MOSFETs may cause deterioration of operation characteristics of semiconductor devices. Therefore, research is being carried out to develop various methods for manufacturing semiconductor devices having improved performance while overcoming limitations due to high integration of semiconductor devices.

### SUMMARY

At least some embodiments of the present disclosure provide a semiconductor device capable of facilitating heat dissipation and a method for manufacturing the same.

At least some embodiments of the present disclosure also provide a semiconductor device having excellent reliability and a method for manufacturing the same.

An embodiment of the present disclosure provides a semiconductor device including: a transistor layer including a semiconductor substrate and gate structures on an upper surface of the semiconductor substrate; an upper substrate on the transistor layer; an upper wiring layer disposed between the transistor layer and the upper substrate and including upper conductive lines; a bonding layer between the upper wiring layer and the upper substrate; and a lower wiring layer disposed on a lower surface of the semiconductor substrate and including lower conductive lines. In an embodiment, the transistor layer may be disposed between the lower wiring layer and the upper wiring layer. In an embodiment, the bonding layer may include a material having higher thermal conductivity than silicon oxide, and a dopant concentration of the upper substrate may be lower than a dopant concentration of the semiconductor substrate.

In an embodiment of the present disclosure, a semiconductor device includes: a transistor layer including a semiconductor substrate and gate structures on an upper surface of the semiconductor substrate; an upper substrate on the transistor layer; an upper wiring layer disposed between the transistor layer and the upper substrate and including upper conductive lines; a bonding layer between the upper wiring layer and the upper substrate; a lower wiring layer disposed on a lower surface of the semiconductor substrate and including lower conductive lines; conductive pads spaced apart from the lower surface of the semiconductor substrate with the lower wiring layer therebetween; and connection bumps respectively disposed on the conductive pads. In an embodiment, a dopant concentration of the upper substrate may be lower than a dopant concentration of the semiconductor substrate.

### BRIEF DESCRIPTION OF THE FIGURES

The accompanying drawings are included to provide a further understanding of the embodiments of the present disclosure, and are incorporated in and constitute a part of this specification. In the drawings:

FIG. 1 is a plan view of a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view of a semiconductor device, taken along line B-B′ of FIG. 1, according to some embodiments of the present disclosure;

FIGS. 5 to 8 are cross-sectional views, taken along line A-A′ of FIG. 1, illustrating a method for manufacturing a semiconductor device according to some embodiments of the present disclosure;

FIG. 9 is a cross-sectional view of a semiconductor device, taken along line A-A′ of FIG. 1, according to some embodiments of the present disclosure;

FIGS. 10 and 11 are cross-sectional views, taken along line A-A′ of FIG. 1, illustrating a method for manufacturing a semiconductor device according to some embodiments of the present disclosure;

FIG. 12 is a cross-sectional view of a semiconductor device, taken along line A-A′ of FIG. 1, according to some embodiments of the present disclosure;

FIG. 13 is a cross-sectional view of a semiconductor device, taken along line A-A′ of FIG. 1, according to some embodiments of the present disclosure;

FIG. 14 is a plan view of a semiconductor device according to some embodiments of the present disclosure;

FIG. 15 is a cross-sectional view taken along line A-A′ of FIG. 14; and

FIGS. 16 and 17 are cross-sectional views of a semiconductor device, taken along line A-A′ of FIG. 14, according to some embodiments of the present disclosure.

### DETAILED DESCRIPTION

Hereinafter, embodiments of the present disclosure will be described in detail with reference to the accompanying drawings.

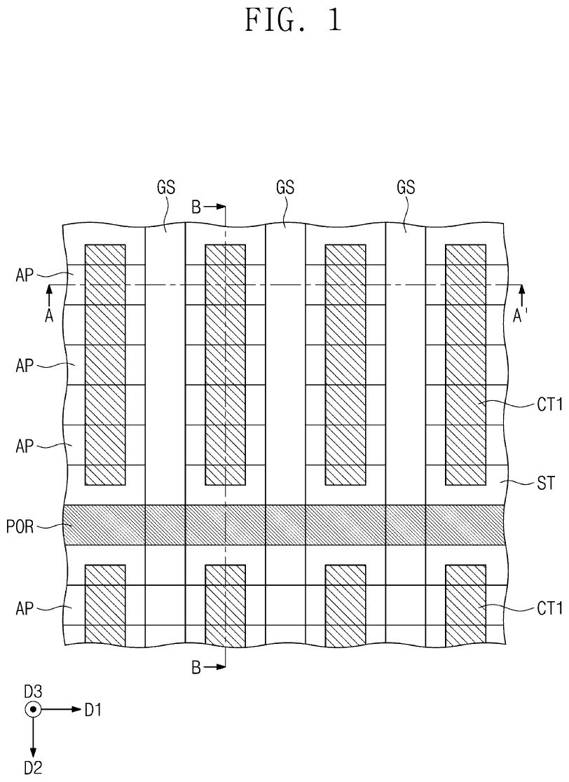

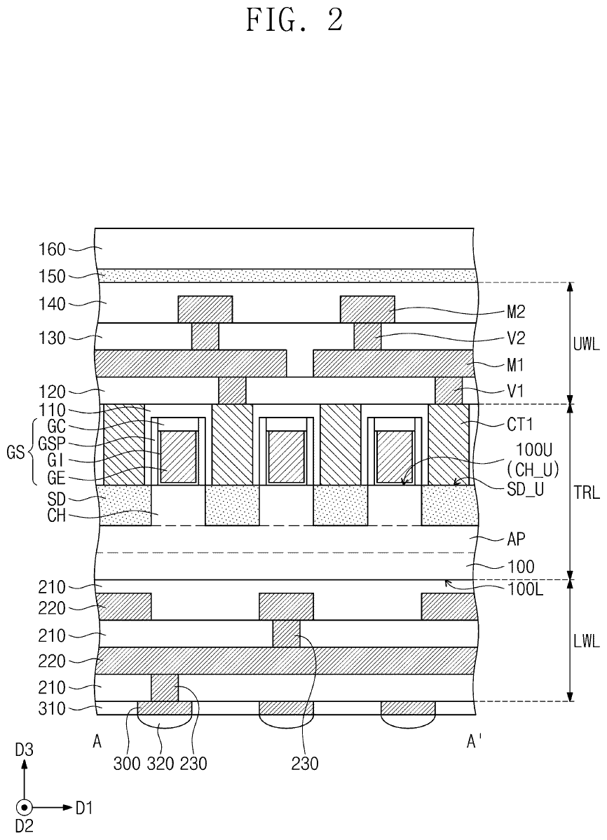

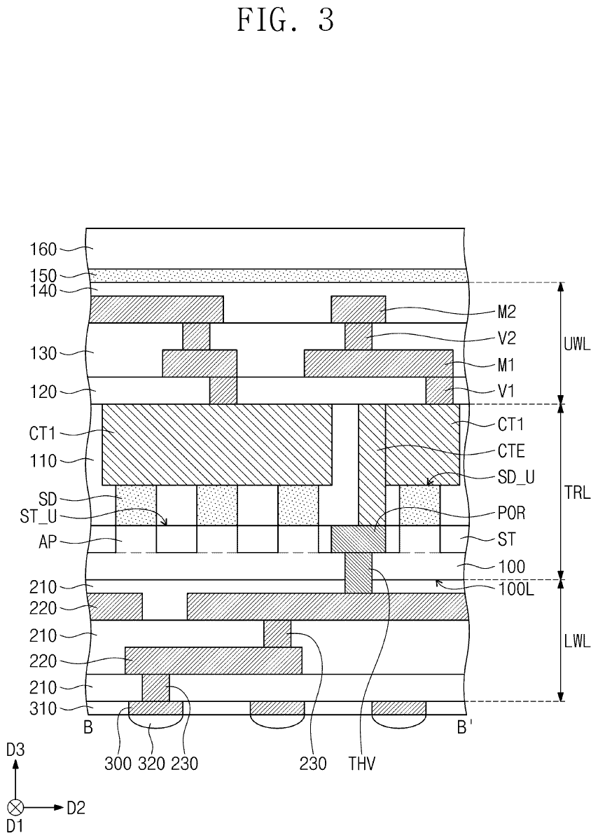

FIG. 1 is a plan view of a semiconductor device according to some embodiments of the present disclosure. FIG. 2 is a cross-sectional view taken along line A-A′ of FIG. 1, and FIG. 3 is a cross-sectional view taken along line B-B′ of FIG. 1.

Referring to FIGS. 1 to 3, a semiconductor substrate 100 including active patterns AP may be provided. The semiconductor substrate 100 may be a silicon substrate, a germanium substrate, or a silicon-germanium substrate. The active patterns AP may extend in a first direction D1 and may be spaced apart from each other in a second direction D2. The first direction D1 and the second direction D2 may be parallel with a lower surface 100L of the semiconductor substrate 100 and may intersect each other. Each of the active patterns AP may protrude from the semiconductor substrate 100 along a third direction D3 perpendicular to the lower surface 100L of the semiconductor substrate 100. Each of the active patterns AP may be a portion of the semiconductor substrate 100 protruding from the semiconductor substrate 100.

A device isolation film ST may be disposed on the semiconductor substrate 100 and may cover side surfaces of the active patterns AP. The device isolation film ST may extend in the first direction D1 between the active patterns AP. The active patterns AP may be spaced apart from each other in the second direction D2 with the device isolation film ST therebetween. The device isolation film ST may include at least one of a silicon oxide film, a silicon nitride film, or a silicon oxynitride film.

A channel pattern CH and source/drain patterns SD may be arranged on each of the active patterns AP. On each of the active patterns AP, the source/drain patterns SD may be spaced apart from each other in the first direction D1 with the channel pattern CH therebetween, and the channel pattern CH may be interposed between the source/drain patterns SD. The device isolation film ST may expose the channel pattern CH and the source/drain patterns SD. An upper surface ST_U of the device isolation film ST may be positioned at a lower height than an uppermost surface CH_U of the channel pattern CH and uppermost surfaces SD_U of the source/drain patterns SD. In the present disclosure, a height may refer to a distance measured from the lower surface 100L of the semiconductor substrate 100 in the third direction D3.

According to some embodiments, the channel pattern CH may be an upper portion of each active pattern AP extending between the source/drain patterns SD. The uppermost surface CH_U of the channel pattern CH may be referred to as an upper surface 100U of the semiconductor substrate 100. The upper surface 100U and the lower surface 100L of the semiconductor substrate 100 may face each other in the third direction D3.

The source/drain patterns SD may be epitaxial patterns formed through a selective growth process using each active pattern AP as a seed. The source/drain patterns SD may include, for example, at least one of silicon, silicon-germanium, or silicon carbide.

According to some embodiments, a power rail POR may be disposed in the device isolation film ST between the active patterns AP. The power rail POR may extend in the first direction D1 between the active patterns AP and may be buried in the device isolation film ST. The power rail POR may have a line shape extending in the first direction D1. The power rail POR may include a conductive material (e.g., metal).

Gate structures GS may be arranged on the upper surface 100U of the semiconductor substrate 100 and may cross the active patterns AP. The gate structures GS may extend in the second direction D2 and may be spaced apart from each other in the first direction D1. According to some embodiments, the gate structures GS may extend in the second direction D2 and cross the power rail POR. The gate structures GS may each vertically (e.g., in the third direction D3) overlap the channel pattern CH on each of the active patterns AP. The gate structures GS may each cover the uppermost surface CH_U of the channel pattern CH and cover side surfaces, facing each other in the second direction D2, of the channel pattern CH. The source/drain patterns SD may be disposed on opposite sides of each of the gate structures GS.

The gate structures GS may each include a gate electrode GE, a gate insulating pattern GI between the gate electrode GE and the channel pattern CH, gate spacers GSP on side surfaces of the gate electrode GE, and a gate capping pattern GC on an upper surface of the gate electrode GE. The gate insulating pattern GI may extend between the gate electrode GE and the gate spacers GSP, and an uppermost surface of the gate insulating pattern GI may be substantially coplanar with an upper surface of the gate electrode GE. The gate electrode GE may cover the uppermost surface CH_U of the channel pattern CH and side surfaces, facing each other in the second direction D2, of the channel pattern CH, and may extend onto the upper surface ST_U of the device isolation film ST. The gate insulating pattern GI may be interposed between the uppermost surface CH_U of the channel pattern CH and the gate electrode GE and between the side surfaces, facing each other in the second direction D2, of the channel pattern CH and the gate electrode GE, and may extend between the upper surface ST_U of the device isolation film ST and the gate electrode GE.

The gate electrode GE may include at least one of: a doped semiconductor, conductive metal nitride, or metal. The gate insulating pattern GI may include at least one of: a silicon oxide film, a silicon nitride film, a silicon oxynitride film, or a high-k film. The high-k film may include a material having a dielectric constant higher than that of a silicon oxide film, such as hafnium oxide (HfO), aluminum oxide (AlO), or tantalum oxide (TaO). The gate spacers GSP and the gate capping pattern GC may include at least one of: a silicon oxide film, a silicon nitride film, or a silicon oxynitride film.

According to some embodiments, each of the gate structures GS, the channel pattern CH, and the source/drain patterns SD may constitute a fin field-effect transistor.

A first interlayer insulating layer 110 may be disposed on the upper surface 100U of the semiconductor substrate 100 and may cover the gate structures GS and the source/drain patterns SD. The first interlayer insulating layer 110 may cover the upper surface ST_U of the device isolation film ST and the power rail POR. The first interlayer insulating layer 110 may include, for example, at least one of: a silicon oxide film, a silicon nitride film, a silicon oxynitride film, or a low-k film.

First contacts CT1 may penetrate an upper portion of the first interlayer insulating layer 110 and may be connected to the source/drain patterns SD. The first contacts CT1 may be disposed on opposite sides of each gate structure GS, and may have a bar shape extending in the second direction D2. The first contacts CT1 may each be connected to the source/drain patterns SD spaced apart from each other in the second direction D2. At least one of the first contacts CT1 may be connected to the power rail POR. For example, the at least one of the first contacts CT1 may include a contact extension portion CTE, which may penetrate the first interlayer insulating layer 110 and may be connected to the power rail POR. The contact extension portion CTE may vertically (e.g., in the third direction D3) extend from a side of the at least one of the first contacts CT1 toward the power rail POR, and may penetrate the first interlayer insulating layer 110 and may be connected to the power rail POR. The contact extension portion CTE may include the same material as that of the at least one of the first contacts CT1 and may be integrated with the at least one of the first contacts CT1.

Second contacts (not shown) may be disposed in the first interlayer insulating layer 110. The second contacts may each penetrate an upper portion of the first interlayer insulating layer 110 and the gate capping pattern GC and may be connected to the gate electrode GE.

The first contacts CT1 and the second contacts may include the same conductive material. The first contacts CT1 and the second contacts may include a metal material, for example, at least one of aluminum, copper, tungsten, molybdenum, or cobalt.

The semiconductor substrate 100, the active patterns AP, the device isolation film ST, the channel pattern CH, the source/drain patterns SD, the gate structures GS, the first interlayer insulating layer 110, the first contacts CT1, and the second contacts may constitute a transistor layer TRL. The transistor layer TRL may include transistors configured with the channel pattern CH, the source/drain patterns SD, and the gate structures GS. According to some embodiments, the transistor layer TRL may further include the power rail POR buried in the device isolation film ST.

An upper wiring layer UWL may be disposed on the upper surface 100U of the semiconductor substrate 100 and on the transistor layer TRL. The upper wiring layer UWL may include a second interlayer insulating layer 120 on the first interlayer insulating layer 110, first vias V1 penetrating the second interlayer insulating layer 120 and connected to the first contacts CT1 and the second contacts, first upper conductive lines M1 arranged on the second interlayer insulating layer 120 and connected to the first vias V1, second vias V2 disposed on the first upper conductive lines M1 and connected to the first upper conductive lines M1, a third interlayer insulating layer 130 disposed on the second interlayer insulating layer 120 and covering the first upper conductive lines M1 and the second vias V2, second upper conductive lines M2 disposed on the third interlayer insulating layer 130 and connected to the second vias V2, and a fourth interlayer insulating layer 140 disposed on the third interlayer insulating layer 130 and covering the second upper conductive lines M2.

The first and second vias V1 and V2, the first and second upper conductive lines M1 and M2, and the second to fourth interlayer insulating layers 120, 130, and 140 may be disposed on the upper surface 100U of the semiconductor substrate 100 and on the transistors of the transistor layer TRL. The source/drain patterns SD of the transistors may be electrically connected to corresponding first vias V1 among the first vias V1 through the first contacts CT1, and the gate electrodes GE of the transistors may be electrically connected to corresponding first vias V1 among the first vias V1 through the second contacts.

The first and second vias V1 and V2 and the first and second upper conductive lines M1 and M2 may include at least one of metal or conductive metal nitride. The second to fourth interlayer insulating layers 120, 130, and 140 may include, for example, at least one of: a silicon oxide film, a silicon nitride film, a silicon oxynitride film, or a low-k film.

For simplicity, the upper wiring layer UWL is illustrated as including the first and second vias V1 and V2 and the first and second upper conductive lines M1 and M2, but the scope of the present disclosure is not limited thereto. The upper wiring layer UWL may further include additional vias and additional upper conductive lines disposed on the second upper conductive lines M2. In this case, the fourth interlayer insulating layer 140 may cover the additional vias and the additional upper conductive lines.

A lower wiring layer LWL may be disposed on the lower surface 100L of the semiconductor substrate 100. The lower wiring layer LWL may include lower conductive lines 220 and lower conductive contacts 230 disposed on the lower surface 100L of the semiconductor substrate 100. The lower conductive lines 220 may be electrically connected to each other through corresponding lower conductive contacts 230 among the lower conductive contacts 230. The lower wiring layer LWL may further include lower insulating films 210 covering the lower conductive lines 220 and the lower conductive contacts 230. The lower conductive lines 220 and the lower conductive contacts 230 may include metal (e.g., copper). The lower insulating films 210 may include, for example, at least one of a silicon oxide film, a silicon nitride film, a silicon oxynitride film, or a low-k film. The lower conductive lines 220 and the lower conductive contacts 230 may constitute a power delivery network.

The transistor layer TRL may further include a through-via THV penetrating the semiconductor substrate 100. The through-via THV may penetrate the semiconductor substrate 100 and may connect the power rail POR and the power delivery network 220 and 230 to each other. The through-via THV may be connected to a corresponding lower conductive line 220 among the lower conductive lines 220 and may vertically extend along the third direction D3 so as to be connected to the power rail POR. The power delivery network 220 and 230 may apply a power supply voltage VDD or ground voltage VSS to the power rail POR through the through-via THV. The power rail POR may apply the power supply voltage VDD or ground voltage VSS to the at least one of the first contacts CT1. The through-via THV may include at least one of metal or a conductive metal nitride.

Conductive pads 300 and a pad insulating film 310 may be disposed on the lower surface 100L of the semiconductor substrate 100 and on the lower wiring layer LWL. The lower wiring layer LWL may be disposed between the lower surface 100L of the semiconductor substrate 100 and the conductive pads 300 and between the lower surface 100L of the semiconductor substrate 100 and the pad insulating film 310. The pad insulating film 310 may cover side surfaces of the conductive pads 300, and each of the conductive pads 300 may penetrate the pad insulating film 310 and may be connected to a corresponding lower conductive contact 230 among the lower conductive contacts 230. The conductive pads 300 may each be electrically connected to the lower conductive lines 220 through the corresponding lower conductive contact 230. The conductive pads 300 may be electrically connected to the power delivery network 220 and 230. The conductive pads 300 may include metal (e.g., copper). The pad insulating film 310 may include, for example, at least one of a silicon oxide film, a silicon nitride film, a silicon oxynitride film, or a low-k film.

Connection bumps 320 may be respectively disposed on the conductive pads 300 and connected to the conductive pads 300. The connection bumps 320 may include a conductive material, and may have a shape of at least one of a solder ball, bump, or pillar.

A bonding layer 150 may be disposed on the upper surface 100U of the semiconductor substrate 100 and on the upper wiring layer UWL. The upper wiring layer UWL may be disposed between the transistor layer TRL and the bonding layer 150. The bonding layer 150 may be disposed on the fourth interlayer insulating layer 140 and electrically insulated (or separated) from the first and second vias V1 and V2 and the first and second upper conductive lines M1 and M2.

The bonding layer 150 may include a material having higher thermal conductivity than silicon oxide. For example, the bonding layer 150 may be an insulating layer including metal. The metal may include, for example, at least one of aluminum, gold, silver, tungsten, copper, cobalt, molybdenum, or ruthenium. According to some embodiments, the bonding layer 150 may include a metal-doped insulating material. For example, the bonding layer 150 may include at least one of metal-doped oxide, metal-doped nitride, or metal-doped oxynitride. For example, the bonding layer 150 may include at least one of metal-doped silicon oxide, metal-doped silicon nitride, or metal-doped silicon oxynitride. For example, the bonding layer 150 may include at least one of aluminum-doped silicon oxide, aluminum-doped silicon nitride, or aluminum-doped silicon oxynitride. According to some embodiments, the bonding layer 150 may include at least one of metal oxide, metal nitride, or metal oxynitride. For example, the bonding layer 150 may include at least one of aluminum oxide, aluminum nitride, or aluminum oxynitride. According to some embodiments, the bonding layer 150 may further include carbon.

An upper substrate 160 may be disposed on the upper surface 100U of the semiconductor substrate 100 and on the bonding layer 150. The bonding layer 150 may be interposed between the upper wiring layer UWL and the upper substrate 160 and may bond the upper wiring layer UWL and the upper substrate 160 to each other. The upper substrate 160 may be an intrinsic semiconductor substrate or a dopant-doped semiconductor substrate. A dopant concentration of the upper substrate 160 may be lower than a dopant concentration of the semiconductor substrate 100. The dopant concentration of the upper substrate 160 may be lower than about 10⁻¹⁵/cm³. For example, the dopant concentration of the upper substrate 160 may be lower than about 10⁻¹²/cm³ and lower than about 10⁻¹⁰/cm³.

As a semiconductor device is highly integrated, heat generated from the transistor layer TRL, the upper wiring layer UWL, and the lower wiring layer LWL may increase. In particular, when the lower wiring layer LWL is formed on the lower surface 100L of the semiconductor substrate 100, a thickness of the semiconductor substrate 100 in the third direction D3 may reduce, causing reduction of thermal conductivity of the semiconductor substrate 100 and deterioration of heat dissipation of the semiconductor device.

According to some embodiments of the present disclosure, the upper substrate 160 disposed on the upper wiring layer UWL may be an intrinsic semiconductor substrate or a semiconductor substrate having a lower dopant concentration than the semiconductor substrate 100. The dopant concentration of the upper substrate 160 may be lower than the dopant concentration of the semiconductor substrate 100 and lower than about 10⁻¹⁵/cm³. Accordingly, thermal conductivity of the upper substrate 160 may be higher than that of the semiconductor substrate 100. In addition, the bonding layer 150 may be an insulating layer including metal. Since the bonding layer 150 includes metal, thermal conductivity of the bonding layer 150 may increase. That is, the thermal conductivity of the upper substrate 160 and the bonding layer 150 may increase. Accordingly, heat generated from the transistor layer TRL, the upper wiring layer UWL, and the lower wiring layer LWL may be easily dissipated through the upper substrate 160 and the bonding layer 150, thus improving reliability of the semiconductor device.

Therefore, a semiconductor device capable of facilitating heat dissipation and having excellent reliability and a method for manufacturing the same may be provided.

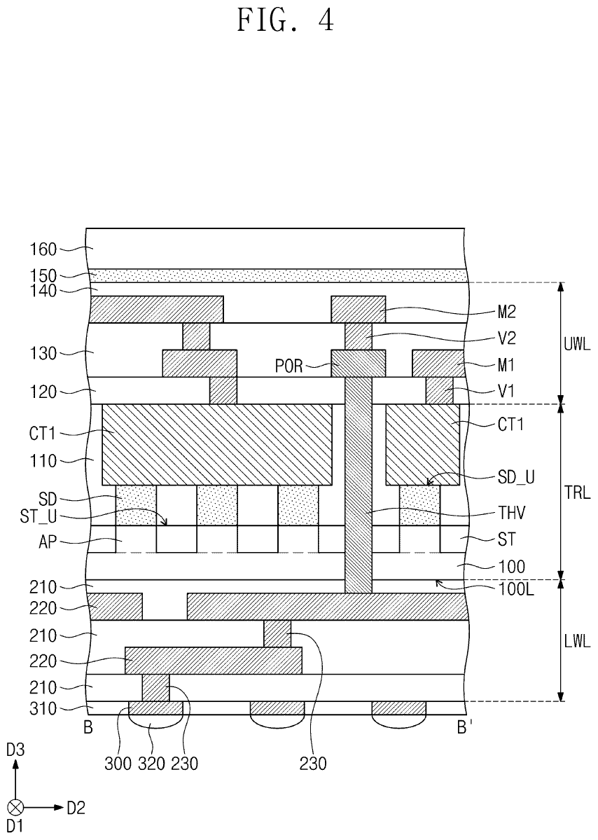

FIG. 4 is a cross-sectional view of a semiconductor device, taken along line B-B′ of FIG. 1, according to some embodiments of the present disclosure. For conciseness, differences from the semiconductor device described with reference to FIGS. 1 to 3 will be mainly described.

Referring to FIGS. 1, 2, and 4, according to some embodiments, the power rail POR may be disposed in the upper wiring layer UWL. For example, the power rail POR may be disposed on the second interlayer insulating layer 120 at the same height, from the lower surface 100L of the semiconductor substrate 100, as the first upper conductive lines M1. The third interlayer insulating layer 130 may be disposed on the second interlayer insulating layer 120 and may cover the power rail POR and the first upper conductive lines M1. The power rail POR may extend in the first direction D1 between the first upper conductive lines M1 and may have a line shape extending in the first direction D1. The power rail POR may be disposed on the gate structures GS and may extend in the first direction D1 to cross the gate structures GS.

The transistor layer TRL may further include a through-via THV penetrating the semiconductor substrate 100. The through-via THV may penetrate the semiconductor substrate 100, the device isolation film ST, the first interlayer insulating layer 110, and the second interlayer insulating layer 120 and may connect the power rail POR and the power delivery network 220 and 230 to each other. The through-via THV may be connected to a corresponding lower conductive line 220 among the lower conductive lines 220 and may vertically extend along the third direction D3 so as to be connected to the power rail POR. The power delivery network 220 and 230 may apply a power supply voltage VDD or ground voltage VSS to the power rail POR through the through-via THV. The power rail POR may be electrically connected to a corresponding second upper conductive line M2 among the second upper conductive lines M2 through a corresponding second via V2 among the second vias V2. At least one of the first contacts CT1 may be electrically connected to the power rail POR through a corresponding first via V1, a corresponding first upper conductive line M1, a corresponding second via V2, and a corresponding second upper conductive line M2. The power rail POR may apply the power supply voltage VDD or ground voltage VSS to the at least one of the first contacts CT1.

The semiconductor device according to the embodiments described above with reference to FIG. 4 may be substantially the same as the semiconductor device described with reference to FIGS. 1 to 3 except for the above-mentioned differences.

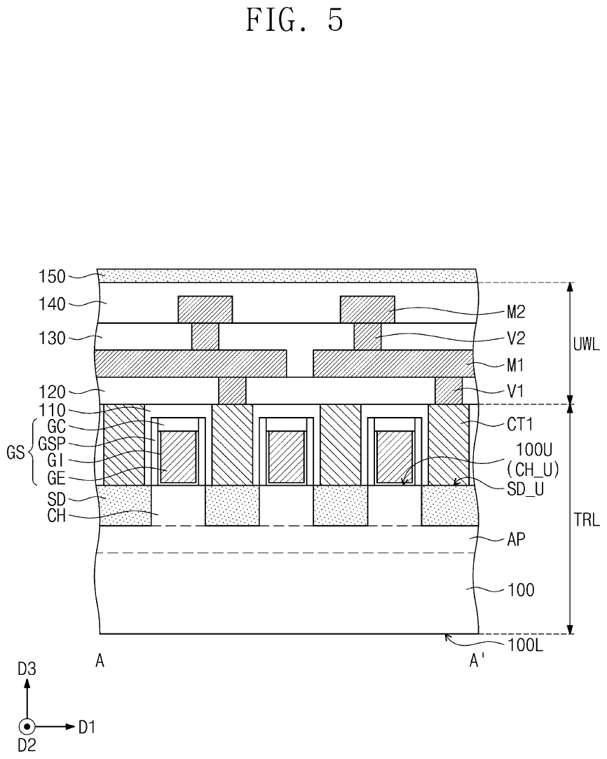

FIGS. 5 to 8 are cross-sectional views, taken along line A-A′ of FIG. 1, illustrating a method for manufacturing a semiconductor device according to some embodiments of the present disclosure. For conciseness, descriptions overlapping with the above descriptions of the semiconductor devices provided with FIGS. 1 to 4 will not be provided.

Referring to FIGS. 1 and 5, the active patterns AP may be formed on the semiconductor substrate 100. The active patterns AP may be formed by patterning an upper portion of the semiconductor substrate 100. The active patterns AP may extend in the first direction D1 and may be spaced apart from each other in the second direction D2. The device isolation film ST (FIGS. 3 and 4) may be formed on the semiconductor substrate 100 and may cover side surfaces of the active patterns AP. Forming the device isolation film ST may include, for example, forming an insulating film covering the active patterns AP on the semiconductor substrate 100, and recessing the insulating film so as to expose upper portions of the active patterns AP.

The channel pattern CH and the source/drain patterns SD may be formed on each of the active patterns AP. On each of the active patterns AP, the source/drain patterns SD may be spaced apart from each other in the first direction D1 with the channel pattern CH therebetween, and the channel pattern CH may be interposed between the source/drain patterns SD. Forming the channel pattern CH and the source/drain patterns SD may include, for example, forming recess regions on opposite sides of the channel pattern CH by patterning the exposed upper portions of the active patterns AP, and performing a selective epitaxial growth process to form the source/drain patterns SD filling the recess regions.

The first interlayer insulating layer 110 may be formed covering the source/drain patterns SD, and the gate structures GS may be formed in the first interlayer insulating layer 110. The gate structures GS may be formed to cross the active patterns AP. The gate structures GS may extend in the second direction D2 and may be spaced apart from each other in the first direction D1. The gate structures GS may each vertically (e.g., in the third direction D3) overlap the channel pattern CH on each of the active patterns AP. The source/drain patterns SD may be disposed on opposite sides of each of the gate structures GS.

Forming the gate structures GS may include, for example, forming an empty region exposing the channel pattern CH in the first interlayer insulating layer 110, and forming the gate insulating pattern GI, the gate electrode GE, the gate capping pattern GC, and the gate spacers GSP in the empty region.

The first contacts CT1 may be formed in the first interlayer insulating layer 110. The first contacts CT1 may penetrate the first interlayer insulating layer 110 and may be connected to the source/drain patterns SD. Although not illustrated, second contacts may be formed in the first interlayer insulating layer 110. The second contacts may each penetrate the first interlayer insulating layer 110 and the gate capping pattern GC and may be connected to the gate electrode GE. Forming the first contacts CT1 and the second contacts may include, for example, forming first contact holes penetrating the first interlayer insulating layer 110 and exposing the source/drain patterns SD, forming second contact holes penetrating the first interlayer insulating layer 110 and the gate capping pattern GC and exposing the gate electrode GE, forming a conductive film filling the first and second contact holes, and planarizing the conductive film until an upper surface of the first interlayer insulating layer 110 is exposed.

Since the semiconductor substrate 100, the active patterns AP, the device isolation film ST, the channel pattern CH, the source/drain patterns SD, the gate structures GS, the first interlayer insulating layer 110, the first contacts CT1, and the second contacts are formed, the transistor layer TRL may be formed.

The upper wiring layer UWL may be formed on the upper surface 100U of the semiconductor substrate 100 and on the transistor layer TRL. Forming the upper wiring layer UWL may include, for example, forming a second interlayer insulating layer 120 on the first interlayer insulating layer 110, forming first vias V1 penetrating the second interlayer insulating layer 120 and connected to the first contacts CT1 and the second contacts, forming, on the second interlayer insulating layer 120, first upper conductive lines M1 connected to the first vias V1, forming, on the first upper conductive lines M1, second vias V2 connected to the first upper conductive lines M1, forming, on the second interlayer insulating layer 120, a third interlayer insulating layer 130 covering the first upper conductive lines M1 and the second vias V2, forming, on the third interlayer insulating layer 130, second upper conductive lines M2 connected to the second vias V2, and forming, on the third interlayer insulating layer 130, a fourth interlayer insulating layer 140 covering the second upper conductive lines M2.

According to some embodiments, the power rail POR described with reference to FIG. 3 may be formed in the transistor layer TRL. In this case, the power rail POR may be formed in the device isolation film ST. According to other embodiments, the power rail POR described with reference to FIG. 4 may be formed in the upper wiring layer UWL. In this case, the power rail POR may be formed on the second interlayer insulating layer 120 at the same height, from the lower surface 100L of the semiconductor substrate 100, as the first upper conductive lines M1.

The bonding layer 150 may be formed on the upper surface 100U of the semiconductor substrate 100 and on the upper wiring layer UWL. The bonding layer 150 may be formed on the fourth interlayer insulating layer 140. Forming the bonding layer 150 may include, for example, depositing an insulating layer on the fourth interlayer insulating layer 140 and doping the insulating layer with metal. For another example, forming the bonding layer 150 may include depositing an insulating layer including metal on the fourth interlayer insulating layer 140 by performing a deposition process using a metal precursor. According to some embodiments, forming the bonding layer 150 may further include injecting carbon into the insulating layer.

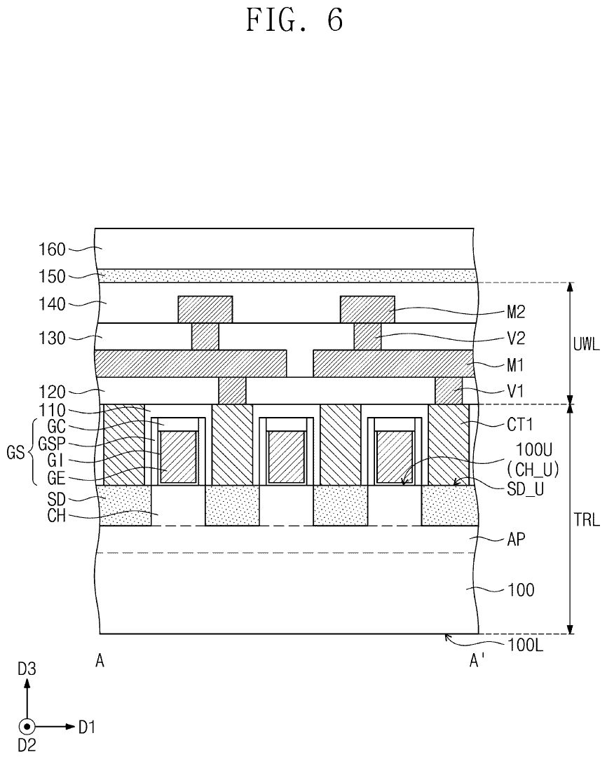

Referring to FIGS. 1 and 6, the upper substrate 160 may be provided on the bonding layer 150. The upper substrate 160 may be bonded to the upper wiring layer UWL through the bonding layer 150. The upper substrate 160 may be an intrinsic semiconductor substrate or a dopant-doped semiconductor substrate. A dopant concentration of the upper substrate 160 may be lower than a dopant concentration of the semiconductor substrate 100. The dopant concentration of the upper substrate 160 may be lower than about 10⁻¹⁵/cm³. For example, the dopant concentration of the upper substrate 160 may be lower than about 10⁻¹²/cm³ and lower than about 10⁻¹⁰/cm³.

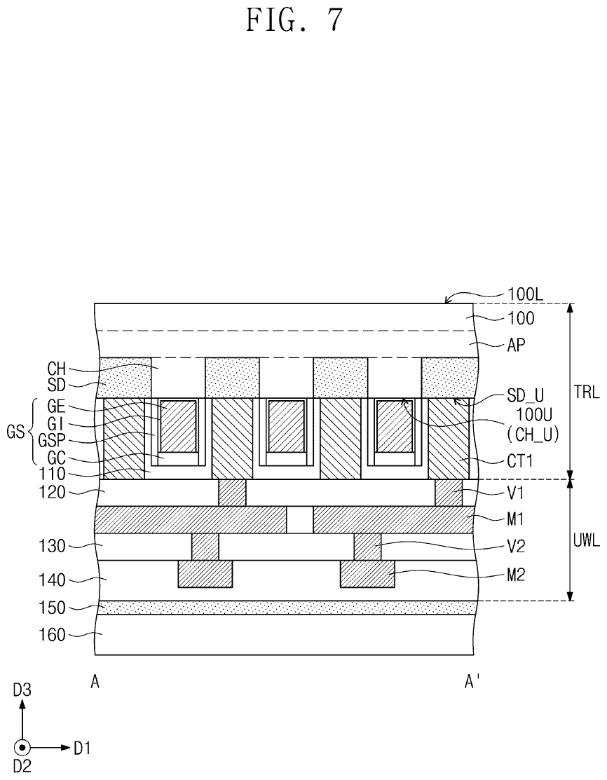

Referring to FIGS. 1 and 7, the structure of FIG. 6 may be capsized so that the lower surface 100L of the semiconductor substrate 100 faces upward and the upper surface 100U of the semiconductor substrate 100 faces downward.

A grinding process may be performed on the lower surface 100L of the semiconductor substrate 100. A lower portion of the semiconductor substrate 100 may be removed through the grinding process, and, accordingly, the thickness of the semiconductor substrate 100 in the third direction D3 may reduce.

According to some embodiments, the through-via THV described with reference to FIG. 3 may be formed penetrating the semiconductor substrate 100 and may be connected to the power rail POR. In this case, forming the through-via THV may include, for example, forming a through-hole extending from the lower surface 100L of the semiconductor substrate 100 toward inside of the semiconductor substrate 100 and exposing the power rail POR, forming an electrode film filling the through-hole on the lower surface 100L of the semiconductor substrate 100, and planarizing the electrode film until the lower surface 100L of the semiconductor substrate 100 is exposed. According to other embodiments, the through-via THV described with reference to FIG. 4 may be formed penetrating the semiconductor substrate 100, the device isolation film ST, the first interlayer insulating layer 110, and the second interlayer insulating layer 120 and may be connected to the power rail POR. In this case, forming the through-via THV may include, for example, forming a through-hole extending from the lower surface 100L of the semiconductor substrate 100 toward inside of the semiconductor substrate 100, penetrating the device isolation film ST, the first interlayer insulating layer 110, and the second interlayer insulating layer 120, and exposing the power rail POR, forming an electrode film filling the through-hole on the lower surface 100L of the semiconductor substrate 100, and planarizing the electrode film until the lower surface 100L of the semiconductor substrate 100 is exposed.

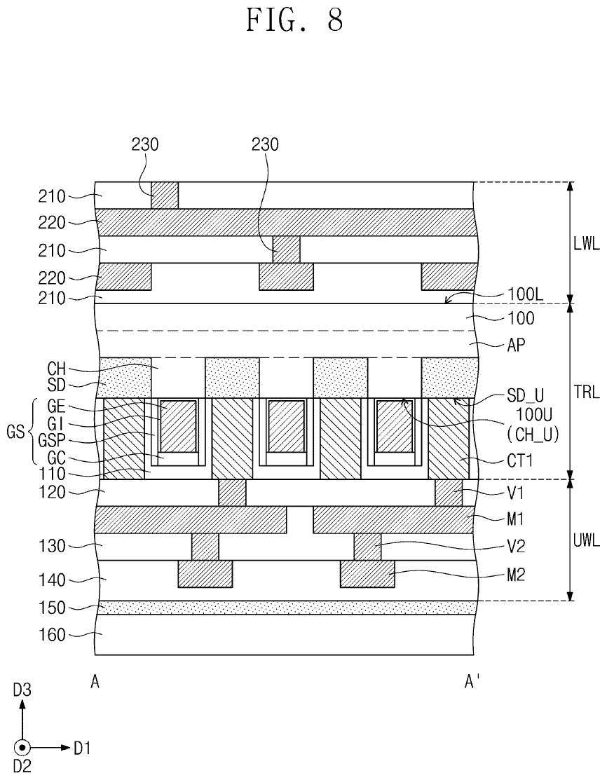

Referring to FIGS. 1 and 8, the lower wiring layer LWL may be formed on the lower surface 100L of the semiconductor substrate 100. Forming the lower wiring layer LWL may include, for example, stacking the lower insulating films 210 on the lower surface 100L of the semiconductor substrate 100 and forming the lower conductive lines 220 and the lower conductive contacts 230 in the lower insulating films 210.

Referring back to FIGS. 1 and 2, the pad insulating film 310 may be formed on the lower surface 100L of the semiconductor substrate 100 and on the lower wiring layer LWL, and the conductive pads 300 may be formed in the pad insulating film 310. The conductive pads 300 may each penetrate the pad insulating film 310 and may be connected to a corresponding lower conductive contact 230 among the lower conductive contacts 230. The connection bumps 320 may be respectively formed on the conductive pads 300.

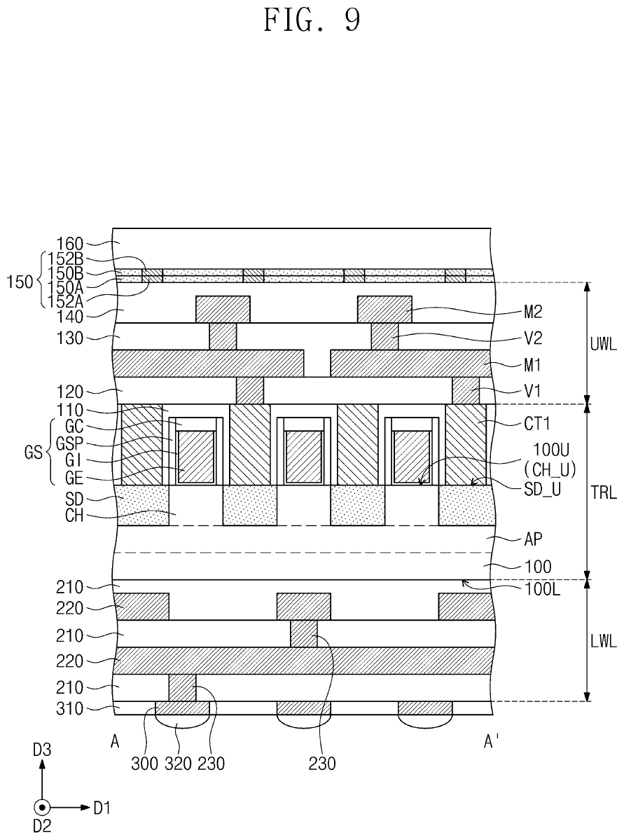

FIG. 9 is a cross-sectional view of a semiconductor device, taken along line A-A′ of FIG. 1, according to some embodiments of the present disclosure. For conciseness, differences from the semiconductor device described with reference to FIGS. 1 to 4 will be mainly described.

Referring to FIGS. 1 and 9, according to some embodiments, the bonding layer 150 may include a first insulating layer 150A adjacent to the upper wiring layer UWL, a second insulating layer 150B adjacent to the upper substrate 160, first metal patterns 152A horizontally spaced apart from each other in the first insulating layer 150A, and second metal patterns 152B horizontally spaced apart from each other in the second insulating layer 150B. The first insulating layer 150A may be in contact (e.g., direct contact) with the second insulating layer 150B, and the first metal patterns 152A may be in contact (e.g., direct contact) with the second metal patterns 152B, respectively. The first insulating layer 150A and the second insulating layer 150B may include an insulating material such as silicon oxide, silicon nitride, and/or silicon oxynitride. The first metal patterns 152A and the second metal patterns 152B may include metal, which may include, for example, at least one of: aluminum, gold, silver, tungsten, copper, cobalt, molybdenum, or ruthenium.

According to the embodiments described with reference to FIG. 9, since the bonding layer 150 includes metal (e.g., the first and second metal patterns 152A and 152B), the thermal conductivity of the bonding layer 150 may increase.

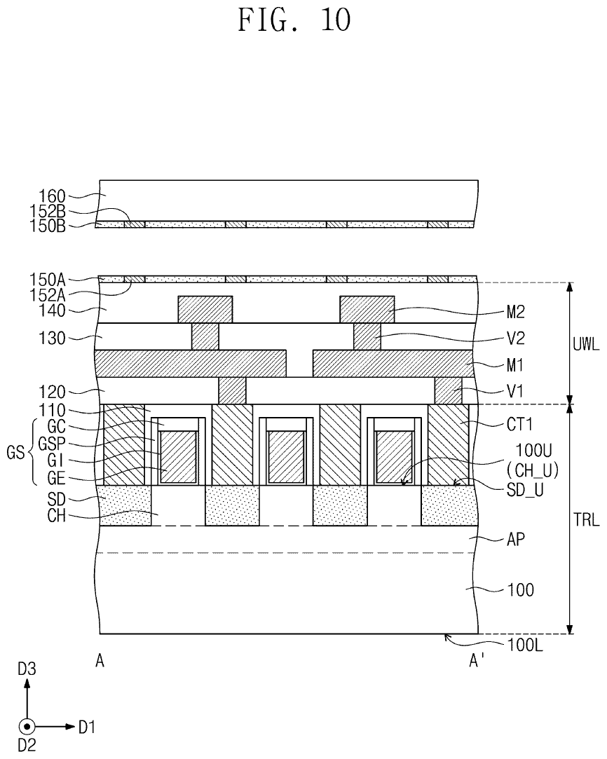

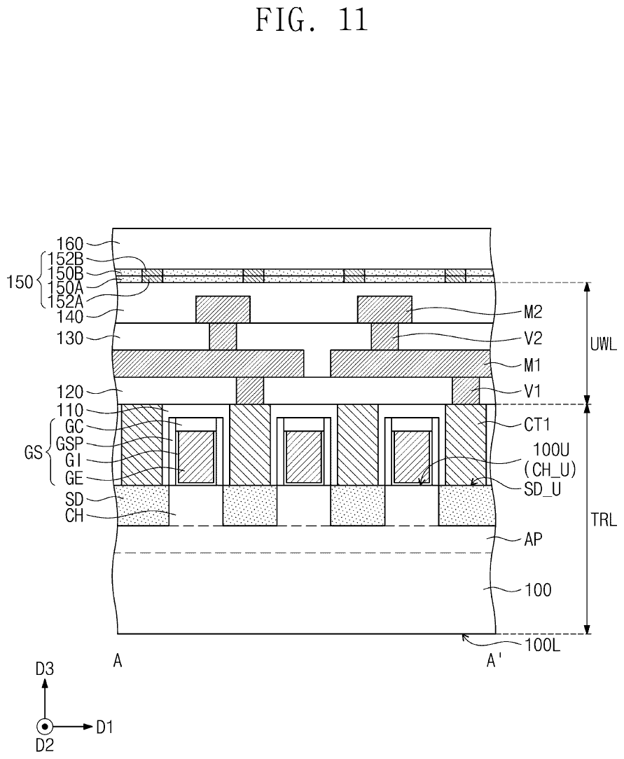

FIGS. 10 and 11 are cross-sectional views, taken along line A-A′ of FIG. 1, illustrating a method for manufacturing a semiconductor device according to some embodiments of the present disclosure. For conciseness, differences from the method for manufacturing a semiconductor device described with reference to FIGS. 5 to 8 will be mainly described.

Referring to FIGS. 1 and 10, the first insulating layer 150A and the first metal patterns 152A may be formed on the upper surface 100U of the semiconductor substrate 100 and on the upper wiring layer UWL. The first insulating layer 150A and the first metal patterns 152A may be formed on the fourth interlayer insulating layer 140. Forming the first metal patterns 152A may include, for example, depositing a first metal film on the fourth interlayer insulating layer 140 and patterning the first metal film. Forming the first insulating layer 150A may include, for example, depositing the first insulating layer 150A covering the first metal patterns 152A on the fourth interlayer insulating layer 140, and planarizing the first insulating layer 150A so as to expose one surface of each of the first metal patterns 152A.

The upper substrate 160 may be provided on the upper wiring layer UWL. The second insulating layer 150B and the second metal patterns 152B may be formed on one surface of the upper substrate 160. Forming the second metal patterns 152B may include, for example, depositing a second metal film on the one surface of the upper substrate 160 and patterning the second metal film. Forming the second insulating layer 150B may include, for example, depositing the second insulating layer 150B covering the second metal patterns 152B on the one surface of the upper substrate 160, and planarizing the second insulating layer 150B so as to expose one surface of each of the second metal patterns 152B.

Referring to FIGS. 1 and 11, the upper substrate 160 may be bonded to the upper wiring layer UWL. The first insulating layer 150A and the second insulating layer 150B may be in contact with each other, and the first metal patterns 152A and the second metal patterns 152B may be in contact with each other. The first insulating layer 150A, the second insulating layer 150B, the first metal patterns 152A, and the second metal patterns 152B may constitute the bonding layer 150. The upper substrate 160 may be bonded to the upper wiring layer UWL through the bonding layer 150. Bonding the upper substrate 160 to the upper wiring layer UWL may be performed using, for example, at least one of a thermal process or a pressing process.

The method for manufacturing a semiconductor device according to the embodiments described above with reference to FIGS. 10 and 11 is substantially the same as the method for manufacturing a semiconductor device described with reference to FIGS. 5 to 8 except for the above-mentioned differences.

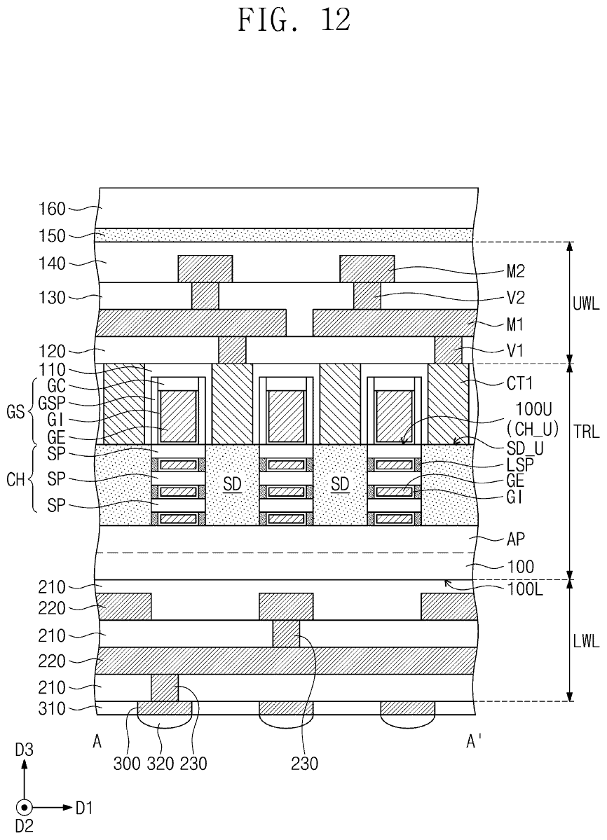

FIG. 12 is a cross-sectional view of a semiconductor device, taken along line A-A′ of FIG. 1, according to some embodiments of the present disclosure. For conciseness, differences from the semiconductor device described with reference to FIGS. 1 to 4 will be mainly described.

Referring to FIGS. 1 and 12, according to some embodiments, the channel pattern CH may include a plurality of semiconductor patterns SP vertically spaced apart from each other along the third direction D3. A lowermost semiconductor pattern SP among the plurality of semiconductor patterns SP may be spaced apart from each active pattern AP along the third direction D3. An upper surface of an uppermost semiconductor pattern SP among the plurality of semiconductor patterns SP may be referred to as the uppermost surface CH_U of the channel pattern CH and as the upper surface 100U of the semiconductor substrate 100.

Each gate structure GS may vertically (e.g., in the third direction D3) overlap the channel pattern CH. The gate electrode GE of each gate structure GS may be disposed on the uppermost semiconductor pattern SP and may extend between the plurality of semiconductor patterns SP and between the lowermost semiconductor pattern SP and each active pattern AP. The gate insulating pattern GI of each gate structure GS may be interposed between the uppermost semiconductor pattern SP and the gate electrode GE and may extend between each of the plurality of semiconductor patterns SP and the gate electrode GE and between each active pattern AP and the gate electrode GE. The gate spacers GSP of each gate structure GS may be disposed on the uppermost semiconductor pattern SP. The gate insulating pattern GI may extend between the gate spacers GSP and the gate electrode GE.

Lower spacer patterns LSP may be disposed between the plurality of semiconductor patterns SP and between the lowermost semiconductor pattern SP and each active pattern AP. A pair of lower spacer patterns LSP among the lower spacer patterns LSP may be horizontally spaced apart from each other with the gate electrode GE therebetween. The gate insulating pattern GI may extend between each of the lower spacer patterns LSP and the gate electrode GE. The lower spacer patterns LSP may include an insulating material such as silicon oxide, silicon nitride, and/or silicon oxynitride.

The channel pattern CH may be interposed between the source/drain patterns SD. The source/drain patterns SD may be connected (e.g., electrically connected) to the plurality of semiconductor patterns SP. The gate electrode GE and the gate insulating pattern GI may be spaced apart from the source/drain patterns SD with the lower spacer patterns LSP therebetween.

According to some embodiments, each of the gate structures GS, the channel pattern CH, and the source/drain patterns SD may constitute a multi-bridge channel field-effect transistor.

The semiconductor device according to the embodiments described above with reference to FIG. 12 is substantially the same as the semiconductor device described with reference to FIGS. 1 to 4 except for the above-mentioned differences. According to some embodiments, the bonding layer 150 of FIG. 12 may be configured in the same manner as the bonding layer 150 of FIG. 9.

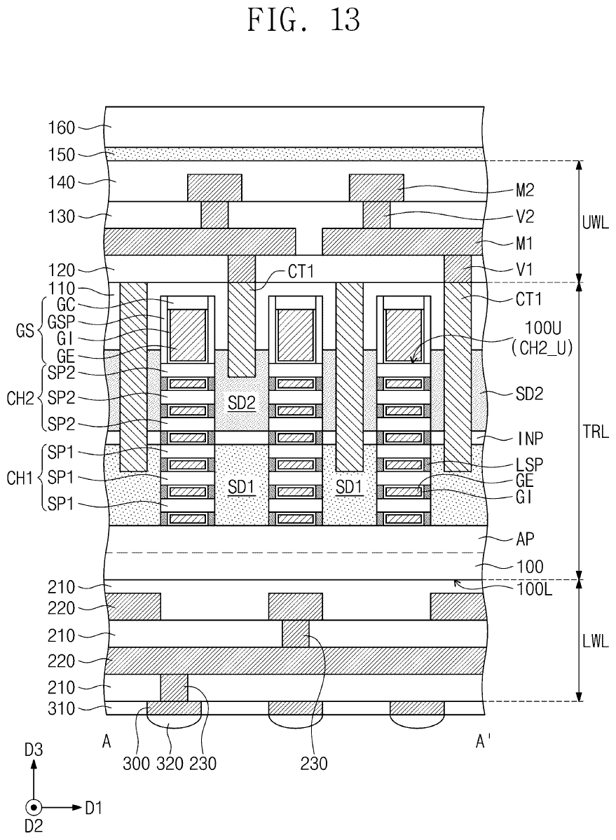

FIG. 13 is a cross-sectional view of a semiconductor device, taken along line A-A′ of FIG. 1, according to some embodiments of the present disclosure. For conciseness, differences from the semiconductor device described with reference to FIGS. 1 to 4 will be mainly described.

Referring to FIGS. 1 and 13, the transistor layer TRL may include a lower channel pattern CH1 and an upper channel pattern CH2 sequentially stacked along the third direction D3 on each active pattern AP. The lower channel pattern CH1 may include a plurality of lower semiconductor patterns SP1 spaced apart from each other along the third direction D3, and the upper channel pattern CH2 may include a plurality of upper semiconductor patterns SP2 spaced apart from each other along the third direction D3. A lowermost lower semiconductor pattern SP1 among the plurality of lower semiconductor patterns SP1 may be vertically (e.g., in the third direction D3) spaced apart from each active pattern AP. A lowermost upper semiconductor pattern SP2 among the upper semiconductor patterns SP2 may be vertically (e.g., in the third direction D3) spaced apart from an uppermost lower semiconductor pattern SP1 among the lower semiconductor patterns SP1. The lower semiconductor patterns SP1 and the upper semiconductor patterns SP2 may include at least one of: silicon (Si), silicon germanium (SiGe), or germanium (Ge). An upper surface of an uppermost upper semiconductor pattern SP2 among the upper semiconductor patterns SP2 may be referred to as an uppermost surface CH2_U of the upper channel pattern CH2 and as the upper surface 100U of the semiconductor substrate 100.

The transistor layer TRL may include lower source/drain patterns SD1 and upper source/drain patterns SD2 sequentially stacked along the third direction D3 on each active pattern AP. The lower source/drain patterns SD1 may be spaced apart from each other in the first direction D1 with the lower channel pattern CH1 therebetween and may be connected to the lower channel pattern CH1. The lower semiconductor patterns SP1 of the lower channel pattern CH1 may be disposed between the lower source/drain patterns SD1 and may be connected to the lower source/drain patterns SD1. The upper source/drain patterns SD2 may be stacked on the lower source/drain patterns SD1 along the third direction D3. The upper source/drain patterns SD2 may be spaced apart from each other in the first direction D1 with the upper channel pattern CH2 therebetween and may be connected to the upper channel pattern CH2. The upper semiconductor patterns SP2 of the upper channel pattern CH2 may be disposed between the upper source/drain patterns SD2 and may be connected to the upper source/drain patterns SD2.

The lower source/drain patterns SD1 may be epitaxial patterns formed using each active pattern AP and the lower semiconductor patterns SP1 as a seed. The lower source/drain patterns SD1 may include at least one of: silicon germanium (SiGe), silicon (Si), or silicon carbide (SiC). The lower source/drain patterns SD1 may be configured to provide a tensile strain or compressive strain to the lower channel pattern CH1. The upper source/drain patterns SD2 may be epitaxial patterns formed using the upper semiconductor patterns SP2 as a seed. The upper source/drain patterns SD2 may include at least one of: silicon germanium (SiGe), silicon (Si), or silicon carbide (SiC). The upper source/drain patterns SD2 may be configured to provide a tensile strain or compressive strain to the upper channel pattern CH2.

An insulating pattern INP may be disposed between the lower source/drain patterns SD1 and the upper source/drain patterns SD2. The upper source/drain patterns SD2 may be electrically separated (or insulated) by the insulating pattern INP from the lower source/drain patterns SD1. The insulating pattern INP may include an insulating material such as silicon oxide, silicon nitride, and/or silicon oxynitride.

Each gate structure GS may be disposed on the upper channel pattern CH2 and may vertically (e.g., in the third direction D3) overlap the lower channel pattern CH1 and the upper channel pattern CH2. The gate electrode GE of each gate structure GS may be disposed on the uppermost upper semiconductor pattern SP2 and may extend between the upper semiconductor patterns SP2. The gate electrode GE of each gate structure GS may extend between the upper channel pattern CH2 and the lower channel pattern CH1. The gate electrode GE of each gate structure GS may extend between the lower semiconductor patterns SP1 and between the lowermost lower semiconductor pattern SP1 and each active pattern AP. The gate insulating pattern GI of each gate structure GS may be interposed between the uppermost upper semiconductor pattern SP2 and the gate electrode GE and may extend between each of the upper semiconductor patterns SP2 and the gate electrode GE, between each of the lower semiconductor patterns SP1 and the gate electrode GE, and between each active pattern AP and the gate electrode GE. The gate spacers GSP of each gate structure GS may be disposed on the uppermost upper semiconductor pattern SP2. The gate insulating pattern GI may extend between the gate spacers GSP and the gate electrode GE.

The lower spacer patterns LSP may be disposed between the upper semiconductor patterns SP2, between the upper channel pattern CH2 and the lower channel pattern CH1, between the lower semiconductor patterns SP1, and between the lowermost lower semiconductor pattern SP1 and each active pattern AP. A pair of lower spacer patterns LSP among the lower spacer patterns LSP may be horizontally spaced apart from each other with the gate electrode GE therebetween. The gate insulating pattern GI may extend between each of the lower spacer patterns LSP and the gate electrode GE. The gate electrode GE and the gate insulating pattern GI may be spaced apart from the lower source/drain patterns SD1, the upper source/drain patterns SD2, and the insulating pattern INP with the lower spacer patterns LSP therebetween. The lower spacer patterns LSP may include an insulating material such as silicon oxide, silicon nitride, and/or silicon oxynitride.

According to some embodiments, each gate structure GS, the lower channel pattern CH1, and the lower source/drain patterns SD1 may constitute a lower transistor, and each gate structure GS, the upper channel pattern CH2, and the upper source/drain patterns SD2 may constitute an upper transistor. Each of the lower transistor and the upper transistor may be a gate-all-around field-effect transistor or a multi-bridge channel field-effect transistor (MBCFET). The lower transistor and the upper transistor may be vertically stacked in the third direction D3 on the semiconductor substrate 100 and may be referred to as stacked transistors.

The first interlayer insulating layer 110 may be disposed on the upper surface 100U of the semiconductor substrate 100 and may cover the gate structures GS and the upper source/drain patterns SD2. At least some of the first contacts CT1 may penetrate the first interlayer insulating layer 110 and the upper source/drain patterns SD2 and may be connected (e.g., electrically connected) to the lower source/drain patterns SD1, and at least some others of the first contacts CT1 may penetrate the first interlayer insulating layer 110 and may be connected (e.g., electrically connected) to the upper source/drain patterns SD2.

The semiconductor device according to the embodiments described above with reference to FIG. 13 is substantially the same as the semiconductor device described with reference to FIGS. 1 to 4 except for the above-mentioned differences. According to some embodiments, the bonding layer 150 of FIG. 13 may be configured in the same manner as the bonding layer 150 of FIG. 9.

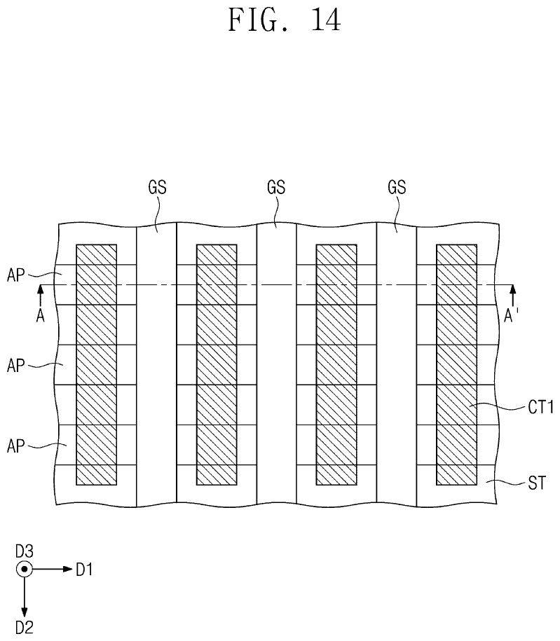

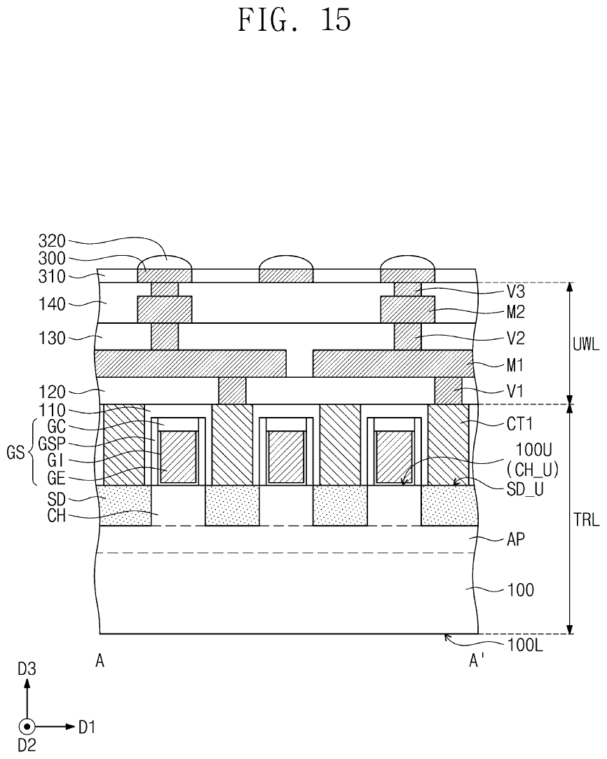

FIG. 14 is a plan view of a semiconductor device according to some embodiments of the present disclosure. FIG. 15 is a cross-sectional view taken along line A-A′ of FIG. 14. For conciseness, differences from the semiconductor device described with reference to FIGS. 1 to 4 will be mainly described.

Referring to FIGS. 14 and 15, the upper wiring layer UWL may be disposed on the transistor layer TRL. According to some embodiments, the lower wiring layer LWL, the power rail POR, the through-via THV, the bonding layer 150, and the upper substrate 160, described with reference to FIGS. 1 to 4, may not be provided. The transistor layer TRL and the upper wiring layer UWL, except the power rail POR and the through-via THV, may be configured in substantially the same manner as the transistor layer TRL and the upper wiring layer UWL described with reference to FIGS. 1 to 4.

According to some embodiments, the semiconductor substrate 100 of the transistor layer TRL may be an intrinsic semiconductor substrate or a dopant-doped semiconductor substrate. The dopant concentration of the semiconductor substrate 100 may be lower than about 10⁻¹⁵/cm³. For example, the dopant concentration of the semiconductor substrate 100 may be lower than about 10⁻¹²/cm³ and lower than about 10⁻¹⁰/cm³. According to some embodiments, the dopant concentration of the semiconductor substrate 100 may decrease in a direction toward the lower surface 100L of the semiconductor substrate 100.

According to some embodiments, the upper wiring layer UWL may further include third vias V3 disposed on the second upper conductive lines M2 and connected to the second upper conductive lines M2. The fourth interlayer insulating layer 140 may cover the second upper conductive lines M2 and the third vias V3.

According to some embodiments, the conductive pads 300 and the pad insulating film 310 may be disposed on the upper surface 100U of the semiconductor substrate 100 and on the upper wiring layer UWL. The upper wiring layer UWL may be disposed between the transistor layer TRL and the pad insulating film 310 and between the transistor layer TRL and the conductive pads 300. The pad insulating film 310 may cover side surfaces of the conductive pads 300. The conductive pads 300 may each penetrate the pad insulating film 310 and may be connected to a corresponding third via V3 among the third vias V3. The conductive pads 300 may each be electrically connected to a corresponding second upper conductive line M2 among the second upper conductive lines M2 through the corresponding third via V3. Connection bumps 320 may be respectively disposed on the conductive pads 300 and connected to the conductive pads 300.

According to the embodiments described above with reference to FIGS. 14 and 15, the semiconductor substrate 100 of the transistor layer TRL may be an intrinsic semiconductor substrate, or the dopant concentration of the semiconductor substrate 100 may be lower than about 10⁻¹⁵/cm³. Accordingly, the thermal conductivity of the semiconductor substrate 100 may increase. Therefore, heat generated from the transistor layer TRL and the upper wiring layer UWL may be easily dissipated through the semiconductor substrate 100, thus improving reliability of the semiconductor device.

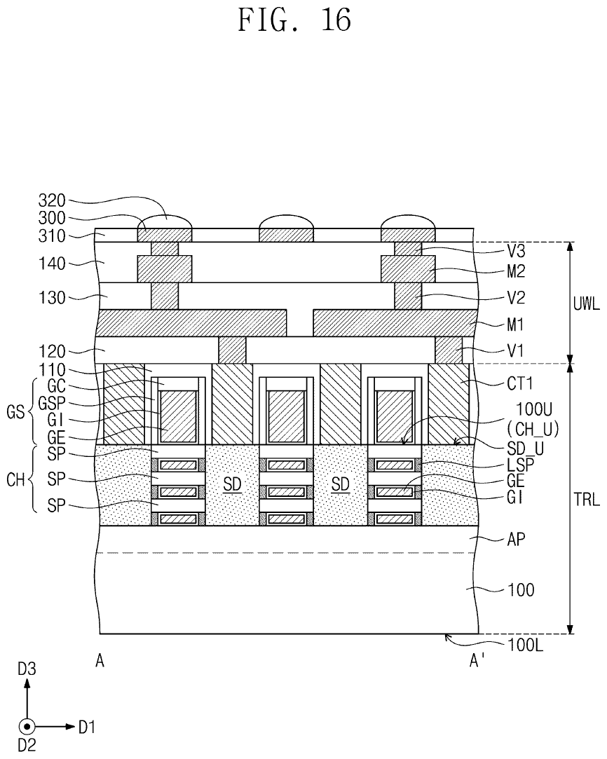

FIG. 16 is a cross-sectional view of a semiconductor device, taken along line A-A′ of FIG. 14, according to some embodiments of the present disclosure. For conciseness, differences from the semiconductor device described with reference to FIGS. 14 and 15 will be mainly described.

Referring to FIGS. 14 and 16, according to some embodiments, the transistor layer TRL may be configured in substantially the same manner as the transistor layer TRL described with reference to FIG. 12. That is, each of the gate structures GS, the channel pattern CH, and the source/drain patterns SD may constitute a multi-bridge channel field-effect transistor. The semiconductor device according to the embodiments described above with reference to FIG. 16 is substantially the same as the semiconductor device described with reference to FIGS. 14 and 15 except for the above-mentioned differences.

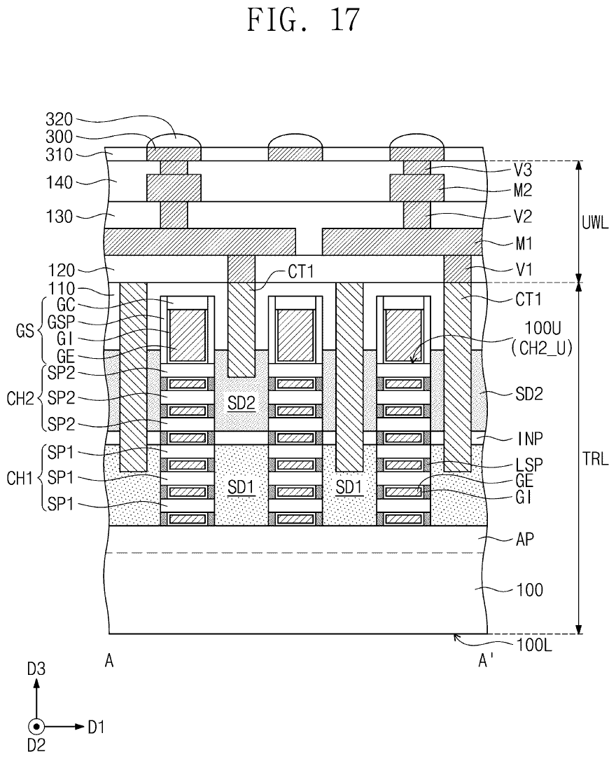

FIG. 17 is a cross-sectional view of a semiconductor device, taken along line A-A′ of FIG. 14, according to some embodiments of the present disclosure. For conciseness, differences from the semiconductor device described with reference to FIGS. 14 and 15 will be mainly described.

Referring to FIGS. 14 and 17, according to some embodiments, the transistor layer TRL may be configured in substantially the same manner as the transistor layer TRL described with reference to FIG. 13. That is, each gate structure GS, the lower channel pattern CH1, and the lower source/drain patterns SD1 may constitute a lower transistor, and each gate structure GS, the upper channel pattern CH2, and the upper source/drain patterns SD2 may constitute an upper transistor. Each of the lower transistor and the upper transistor may be a gate-all-around field-effect transistor or a multi-bridge channel field-effect transistor (MBCFET). The lower transistor and the upper transistor may be vertically stacked in the third direction D3 on the semiconductor substrate 100 and may be referred to as stacked transistors. The semiconductor device according to the present embodiments is substantially the same as the semiconductor device described with reference to FIGS. 14 and 15 except for the above-mentioned differences.

According to the embodiments described with reference to FIG. 17, an upper substrate may be an intrinsic semiconductor substrate or a semiconductor substrate having a relatively low dopant concentration, and a bonding layer may include a material having higher thermal conductivity than silicon oxide. Accordingly, the thermal conductivity of the upper substrate and the bonding layer may increase, and heat generated from a transistor layer and a wiring layer of a semiconductor device may be easily dissipated through the upper substrate and the bonding layer. As a result, the reliability of the semiconductor device may be improved.

Therefore, a semiconductor device capable of facilitating heat dissipation and having excellent reliability and a method for manufacturing the same may be provided.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

What is claimed is:

1. A semiconductor device comprising:
a transistor layer including a semiconductor substrate and one or more gate structures on an upper surface of the semiconductor substrate;
an upper substrate on the transistor layer;
an upper wiring layer disposed between the transistor layer and the upper substrate and including one or more upper conductive lines;
a bonding layer between the upper wiring layer and the upper substrate; and
a lower wiring layer disposed on a lower surface of the semiconductor substrate and including one or more lower conductive lines,
wherein the transistor layer is disposed between the lower wiring layer and the upper wiring layer,
the bonding layer includes a material having a thermal conductivity higher than a thermal conductivity of silicon oxide, and
a dopant concentration of the upper substrate is lower than a dopant concentration of the semiconductor substrate.

2. The semiconductor device of claim 1, wherein the bonding layer is an insulating layer including metal.

3. The semiconductor device of claim 1, further comprising
a power rail disposed in the transistor layer or the upper wiring layer,
wherein the transistor layer further includes a through-via penetrating the semiconductor substrate and connecting a corresponding lower conductive line among the one or more lower conductive lines and the power rail.

4. The semiconductor device of claim 3,
wherein the transistor layer further includes at least one source pattern and at least one drain pattern disposed on the semiconductor substrate and at opposite sides of each of the gate structures, and
the power rail is electrically connected to at least one of the at least one source pattern or the at least one drain pattern.

5. The semiconductor device of claim 1, further comprising:
one or more conductive pads spaced apart from the lower surface of the semiconductor substrate with the lower wiring layer therebetween; and
one or more connection bump respectively disposed on the conductive pads,
wherein the one or more conductive pads are electrically connected to the one or more lower conductive lines.

6. The semiconductor device of claim 1, wherein the bonding layer includes a metal-doped insulating material.

7. The semiconductor device of claim 1, wherein the bonding layer includes at least one of a metal oxide, a metal nitride, or a metal oxynitride.

8. The semiconductor device of claim 1, wherein the bonding layer includes:
a first insulating layer adjacent to the upper wiring layer;
a second insulating layer adjacent to the upper substrate;
a plurality of first metal patterns horizontally spaced apart from each other in the first insulating layer; and
a plurality of second metal patterns horizontally spaced apart from each other in the second insulating layer,
wherein the plurality of first metal patterns are respectively in contact with the plurality of second metal patterns, and
the first insulating layer is in contact with the second insulating layer.

9. The semiconductor device of claim 1, wherein the transistor layer further includes:
an active pattern protruding from the semiconductor substrate in a vertical direction perpendicular to the lower surface of the semiconductor substrate;
a device isolation film covering a side surface of the active pattern;
a channel pattern on the active pattern; and
at least one source pattern and at least one drain pattern disposed on the active pattern and spaced apart from each other with the channel pattern therebetween,
wherein each of the one or more gate structures is disposed on the channel pattern, and
an upper surface of the device isolation film is positioned at a lower height than uppermost surfaces of the at least one source pattern, the at least one drain pattern, and the channel pattern.

10. The semiconductor device of claim 9,
wherein the channel pattern includes a plurality of semiconductor patterns spaced apart from the active pattern in the vertical direction, and
a gate electrode of each of the gate structures extends between the plurality of semiconductor patterns.

11. The semiconductor device of claim 10, wherein the at least one source pattern and the at least one drain pattern are connected to the plurality of semiconductor patterns.

12. The semiconductor device of claim 11, wherein the at least one source pattern and the at least one drain pattern include:
at least one lower source pattern and at least one lower drain pattern; and
at least one upper source pattern and at least one upper drain pattern spaced apart from the at least one lower source pattern and the at least one lower drain pattern in the vertical direction,
wherein the at least one lower source pattern and the at least one lower drain pattern are spaced apart from each other with lower semiconductor patterns, among the plurality of semiconductor patterns, therebetween and connected to the lower semiconductor patterns, and
the at least one upper source pattern and the at least one upper drain pattern are spaced apart from each other with upper semiconductor patterns, among the plurality of semiconductor patterns, therebetween and connected to the upper semiconductor patterns.

13. A semiconductor device comprising:
a transistor layer including a semiconductor substrate and one or more gate structures on an upper surface of the semiconductor substrate;
an upper substrate on the transistor layer;
an upper wiring layer disposed between the transistor layer and the upper substrate and including one or more upper conductive lines;
a bonding layer between the upper wiring layer and the upper substrate;
a lower wiring layer disposed on a lower surface of the semiconductor substrate and including one or more lower conductive lines;
one or more conductive pads spaced apart from the lower surface of the semiconductor substrate with the lower wiring layer therebetween; and
one or more connection bumps respectively disposed on the one or more conductive pads,
wherein a dopant concentration of the upper substrate is lower than a dopant concentration of the semiconductor substrate.

14. The semiconductor device of claim 13, wherein the dopant concentration of the upper substrate is lower than 10⁻¹⁵/cm³.

15. The semiconductor device of claim 13, wherein the bonding layer is an insulating layer including a metal.

16. The semiconductor device of claim 13, wherein the bonding layer includes a metal-doped insulating material.

17. The semiconductor device of claim 13, wherein the bonding layer includes at least one of a metal oxide, a metal nitride, or a metal oxynitride.

18. The semiconductor device of claim 13, wherein the bonding layer includes:
a first insulating layer adjacent to the upper wiring layer;
a second insulating layer adjacent to the upper substrate;
a plurality of first metal patterns horizontally spaced apart from each other in the first insulating layer; and
a plurality of second metal patterns horizontally spaced apart from each other in the second insulating layer,
wherein the plurality of first metal patterns are respectively in contact with the plurality of second metal patterns, and
the first insulating layer is in contact with the second insulating layer.

19. The semiconductor device of claim 13, wherein the transistor layer further includes:
an active pattern protruding from the semiconductor substrate in a vertical direction perpendicular to the lower surface of the semiconductor substrate;
a device isolation film covering a side surface of the active pattern;
a channel pattern on the active pattern; and
at least one source pattern and at least one drain pattern disposed on the active pattern and spaced apart from each other with the channel pattern therebetween,
wherein each of the one or more gate structures is disposed on the channel pattern, and
the one or more upper conductive lines are electrically connected to a gate electrode of each of the one or more gate structures and the at least one source pattern and the at least one drain pattern.

20. The semiconductor device of claim 19, further comprising
a power rail disposed in the device isolation film of the transistor layer or the upper wiring layer,
wherein the transistor layer further includes a through-via penetrating the semiconductor substrate and connecting a corresponding lower conductive line among the one or more lower conductive lines and the power rail.
